(19) United States
(12) Patent Application Publication
(10) Pub. No.: US 2011/0100810 A1
(43) Pub. Date: May 5, 2011

(54) CHIP INTEGRATED ION SENSOR

(75) Inventor: Matthias Merz, Leuven (BE)

(73) Assignee: NXP B.V., Eindhoven (NL)

(21) Appl. No.: 13/001,804

(22) PCT Filed: May 19, 2009
(86) PCT No.: PCT/IB09/52072

§ 371 Date: Dec. 29, 2010

(30) Foreign Application Priority Data
Jun. 30, 2008 (EP) 08104588.2
May 19, 2009 (IB) PCT/IB2009/052072

(51) Int. Cl. G01N 27/414; H01L 29/772; H01L 21/335

(52) U.S. Cl. 204/406; 257/253; 438/49; 204/416; 257/E29.242; 257/E21.4

(57) ABSTRACT

A chip integrated ion sensor is provided, which comprises a substrate having arranged thereon an electrolyte insulator semiconductor structure and a reference electrode. In particular, the electrolyte insulator semiconductor (EIS) structure may be formed on a chip already processed, i.e. the EIS structure may be formed in a Back End process on an already formed chip comprising a plurality of formed electronic components. In particular, the ion sensor may be adapted to form an ion concentration sensor, e.g. a pH sensor, i.e. may form a pH sensor. The reference electrode may be a non-polarizable electrode. In particular, the reference electrode may comprise Ag or AgCl as material.

### FIELD OF THE INVENTION

The invention relates to a chip integrated ion sensor, in particular to a chip integrated ion concentration sensor for producing a signal indicative of an ion concentration within a solution.

The invention further relates to a method of producing a chip integrated ion sensor.

### BACKGROUND OF THE INVENTION

Nowadays a plurality of sensors is integrated into electronic chips. For example, it is interesting to implement pH sensors into electronic chips, since the pH value is an integral parameter of every (aqueous) solution, it describes to which degree the solution is alkaline or acidic. Over a wide range it is well approximated by: pH=−log [H⁺] with [H⁺] denoting the proton concentration of the solution in mol/L. pH measurement is a routine task in industry and laboratories for process control and analysis. However, it could also become interesting for a wider application range if the cost of the pH measurement units (sensor plus electronics) become sufficiently cheap. For example, there is a large potential for pH measurement to monitor the quality of (liquid) perishables in the supply chain or even at the customer himself.

Conventional pH sensors include glass electrodes and chemical indicators (e.g. liquids or paper that changes colour depending on the actual pH value). Because of size and/or detection principle they can hardly be miniaturised and integrated into a silicon chip. Yet miniaturisation and integration would enable a substantial cost reduction paving the way for a range of new applications.

More than 30 years ago P. Bergveld invented the Ion Sensitive Field Effect Transistor (ISFET). The device is a modified FET with the gate dielectric in direct contact with the liquid analyte instead of the usual metal- or polysilicon gate (an additional reference electrode defines the potential of the liquid). Changes in pH alter the surface potential of the gate dielectric and modulate the source drain current making the ISFET a pH sensor.

Conventional ISFETs are very small but cannot be integrated into a CMOS chip because the direct contact of the liquid with the gate dielectric can also affect other transistors in close proximity and destroy the device due to corrosion and uptake of ions (shift in threshold voltage of transistors caused by Na diffusing into the gate regions). Extended Gate Field Effect Transistors (EGFET) solves the problem in that a dielectric sensor layer is connected on top of the device via a metal contact to the transistor gate. However, this configuration separates the sensor from the electronics layer, the latter being well protected from the liquid by several impermeable oxide and nitride passivation layers.

However, there may be a need to provide an alternative ion sensor that is easy to manufacture.

### OBJECT AND SUMMARY OF THE INVENTION

It may be an object of the present invention to provide an alternative ion sensor that is easy to manufacture and which can be integrated into a chip and a method of manufacturing an alternative ion sensor.

In order to achieve the object defined above, a chip integrated ion sensor and a method of manufacturing the same according to the independent claims are provided. Advantageous embodiments are described in the dependent claims.

According to an exemplary aspect a chip integrated ion sensor, in particular a pH sensor, is provided, which comprises a substrate having arranged thereon an electrolyte insulator semiconductor structure and a reference electrode.

In particular, the electrolyte insulator semiconductor (EIS) structure may be formed on a chip already processed, i.e. the EIS structure may be formed in a Back End process on an already formed chip comprising a plurality of formed electronic components. In particular, the ion sensor may be adapted to form an ion concentration sensor, e.g. a pH sensor. The reference electrode may be a non-polarizable electrode. In particular, the reference electrode may comprise Ag or AgCl as material.

According to an exemplary aspect a method manufacturing a chip integrated electrolyte insulator semiconductor ion sensor is provided, the method comprises providing a substrate comprising at least one electronic component, forming an ion sensor on the substrate, and forming a reference electrode of the substrate.

By using a method of manufacturing an chip integrated ion sensor according to an exemplary aspect of the invention it may be possible to integrate the forming of the EIS structure into standard semiconductor processing, e.g. by first forming a substrate or chip and then forming the EIS structure. That is, no change in standard process flow may be necessary but only additional steps may be added at the end of the processing. Since standard processes may be used in forming the substrate and the EIS structure it may be possible to manufacture low cost devices which can be used in a wide range of applications, e.g. as pH sensors for RFID tags in supply chain monitoring of perishables.

Next, further exemplary embodiments of the ion sensor are described. However, these embodiments also apply to the method of manufacturing the ion sensor.

According to another exemplary embodiment of the ion sensor the substrate forms a chip processed according to CMOS processes. Alternatively to a processing by CMOS processes also other known semiconductor processes like NMOS or PMOS may be used. Using standard CMOS processing steps, e.g. CMOS techniques, in the manufacturing of the substrate may enable low cost manufacturing of the chip integrated ion sensor. The essential feature of this exemplary embodiment may be the miniaturised integration of an EIS structure including the reference electrode on top of a CMOS chip. No changes to the process flow may be required only a few steps may be added before packaging. Thus, production of these devices can benefit from the high volume low cost manufacturing of common CMOS chips

According to another exemplary embodiment of the ion sensor the electrolyte insulator semiconductor structure forms a capacity, wherein the reference electrode, is adapted to set a potential of an electrolyte. In particular, the electrolyte placed in the electrolyte insulator semiconductor structure may then form one electrode of an EIS capacity or capacitor.. In particular, the electrolyte insulator semiconductor structure may form a capacitor comprising two electrodes, e.g. the reference electrode and a sensor electrode.

According to another exemplary embodiment the ion sensor further comprises a dielectric layer and a sensor electrode, wherein the dielectric layer is formed between the reference electrode and the sensor electrode. In particular, the dielectric layer may be formed on top of the sensor electrode, for instance it may cover the whole sensor electrode, such that the sensor electrode may be protected from degrading, like corrosion. The thickness of the dielectric layer may be chosen according to predetermined criteria, e.g. sensitivity of the ion sensor or corrosion resistance. In particular, the dielectric may be used to sense pH/ion concentration together with the sensor electrode, i.e. may form an integral part of a sensing capacity. For example, the dielectric layer may comprise or may consist of Ta₂O₅, SiO₂, TiO₂, Si₃N₄, Al₂O₃, SnO₂, or ZrO₂ or a mixture or multilayer structure thereof. The thickness of the dielectric layer may be between 10 nm and several hundred nm, e.g. 500 nm and may be chosen according to the conditions, e.g. may be chosen such that a sensor electrode arranged underneath is sufficiently protected and/or may be chosen to ensure a predetermined sensitivity. The sensitivity may be adjustable by choosing the thickness of the dielectric layer, since the thickness may affect the sensor capacitance and thus may also affect sensitivity.

According to another exemplary embodiment of the ion sensor the sensor electrode forms a second electrode of the capacity, wherein the sensor electrode comprises a semiconductor material. In particular, the two electrodes may form the electrodes of a capacitor and may be arranged laterally or vertically offset from each other. Preferably, both electrodes may be contacted through contact pads or contact areas arranged on top of the substrate. That is, the sensor electrode and the reference electrode may be formed directly on contact pads or contact areas formed in the substrate. The semiconductor material may be silicon or another suitable semiconductor.

According to another exemplary embodiment of the ion sensor the semiconductor material is doped. In particular, the amount of dopant corresponds to a predetermined dopant level. As a dopant every known dopant may be suitable. The predetermined dopant level may be chosen in such a way that positively charged ions are not injected into a dielectric layer but rather be attracted by the reference electrode.

According to another exemplary embodiment of the ion sensor the ion sensor is adapted that the reference electrode is negatively biased with respect to the dielectric layer. In particular, the reference electrode may be negatively biased throughout a portion or the whole range of the ion sensing, e.g. in the range of ion concentration which shall be monitored.

Thus, it may be possible to ensure that a flatband voltage is negative throughout at least a part or the whole range of the ion measurement, e.g. the ion concentration measurement like the pH measurement. Doping the semiconductor material of the sensor electrode, wherein the dopant concentration in the semiconductor material is set to a predetermined level, may ensure this negative flatband voltage. This predetermined level may be chosen in such a way that a negative flatband voltage may be ensured. That is, the predetermined dopant level may be chosen in such a way that a negatively biased reference electrode with respect to the dielectric layer is achievable.

The doping may also prevent injection of ions (esp. Na) into the dielectric layer, which may cover the sensor electrode, to cause a shift in the flatband voltage which could otherwise be misinterpreted as a change in pH value. In order to possibly prevent these errors and improve the long-term stability the semiconductor layer may be doped such that the flatband voltage is negative throughout the entire ion measurement range, e.g. corresponding to a pH measurement range. That way the reference electrode may always be negatively biased with respect to the dielectric layer thus positively charged ions may not injected into the dielectric layer but rather be attracted by the reference electrode.

According to another exemplary embodiment of the ion sensor the ion sensor is adapted in such a way that a liquid the ion concentration of which has to be measured comes into contact with the dielectric layer. In particular, the liquid may only come into contact with the dielectric layer and in particular not with the sensor electrode. For example the dielectric layer may cover the whole sensor electrode so that the sensor electrode is protected from the liquid, i.e. does not come into direct contact with the liquid. This, in a side effect, may also protect the sensor electrode from degrading effects possibly caused by the liquid, e.g. caused by ions in the liquid. However, the main purpose of the dielectric layer may be the forming of an integral part of the capacity of the EIS structure.

According to another exemplary embodiment the ion sensor further comprises a control unit, wherein the control unit is adapted to maintain a capacitance value of the capacity at a predetermined level. In particular, the predetermined level may be a constant level, i.e. the capacitance value may be a constant value.

For example, pH may be measured by the constant capacitance method. A capacitance value may be selected between the min and max capacitance (e.g. near the flatband voltage) and a feedback loop may be implemented to adjusts the voltage on the reference electrode (i.e. gate voltage) such that the measured capacitance remains constant at the predefined value. This change in the voltage on the reference electrode may then reflect the pH change of an electrolyte. The actual pH value may be calculated or determined from the voltage change and initial value with a suitable calibration curve. In principle it may also be possible to determine the pH value from measuring a full C-V curve and extracting the flatband voltage.

According to another exemplary embodiment of the ion sensor the control unit comprises a feedback loop which is adapted to adjust a voltage level on the reference electrode.

According to another exemplary embodiment the ion sensor further comprises a processing unit, wherein the processing unit is adapted to calculate an ion concentration based on the voltage level on the reference electrode.

When the capacitance value of the capacity is maintained at a constant value the voltage level of the reference electrode may be a suitable variable to determine the ion concentration of a liquid coming into contact with a dielectric layer arranged between the reference electrode and a sensor electrode.

It should be noted that the control unit, the feedback unit, and/or processing unit may be formed by a single unit or may be formed by several units. In particular, the unit(s) may be formed in the substrate, e.g. by way of a specific circuitry or chip formed in the substrate. However, the units may also be formed or may also be arranged outside of the substrate. In this case contact terminals may be provided to form an output terminal for measured variables, e.g. the voltage level and/or the value of capacitance.

According to another exemplary embodiment of the ion sensor the substrate is formed by a chip which comprises a plurality of electronic circuits.

According to another exemplary embodiment of the ion sensor the plurality of electronic circuits comprises at least one out of the group of electronic circuits consisting of data acquisition circuits, processing circuits, memory circuits, power module, and RFID unit. For example, the data acquisition circuits may comprise AD and/or DA converter, while the processing unit may be formed by small processors. The provision of an RFID unit may enable data transfer, e.g. in case the ion sensor is used for supply chain monitoring of food or other perishables. In this context it should be noted that at least the materials coming into contact with the electrolyte to be measured may be chosen to be biocompatible or food safe.

According to another exemplary embodiment the ion sensor further comprises a third electrode which forms a counter electrode.

In particular, the third electrode may be adapted to take currents from the sensor electrode or working electrode, i.e. the third electrode may prevent that current flows across the reference electrode during measurement, which current otherwise may cause a shift in potential of the ion sensor, in particular in the potential of an electrolyte which is measured with respect to its ion concentration. The provision of a third or counter electrode may in particular be useful in cases in which high currents flow, e.g. due to a low thickness of the dielectric layer covering the sensor electrode or working electrode. Due to the provision of a third electrode which forms a so-called counter electrode it may be possible to reduce current flow across the reference electrode during measurement which otherwise might cause a shift in potential of the electrolyte and thus errors in the flatband/gate voltage and pH values.

According to another exemplary embodiment the ion sensor further comprises an integrated potentiostat which is adapted to control the counter electrode.

Summarizing an exemplary aspect of the invention may describe a chip integrated pH sensor and method for manufacturing the same. It is based on an IC with the ion sensor or sensor module being added as the final step just before packaging. The module comprises an Electrolyte Insulator Semiconductor (EIS) capacitor and reference electrode for pH measurement connected to contacts on top of the IC. That way standard (CMOS) flow may be used throughout the entire processing, which enables low cost devices. Compared to EGFETs the chip integrated ion sensor according to an exemplary aspect of the invention may be advantageous since it may prevent at least some the disadvantages of the same, e.g. that the metal contact between top sensor dielectric and gate dielectric is electrically floating, so that charges (e.g. from in diffusing ions or a leaky gate dielectric) accumulate on it causing a change in transistor current which is misinterpreted as a pH change. Additionally, the chip integrated ion sensor may not be sensitive to light, so that a change in light intensity may not cause errors in pH readings. The invention describes a pH sensor based on the EIS principle and its miniaturised integration into a CMOS device. Electrolyte Insulator Semiconductor (EIS) structures are very similar to MOS (Metal Oxide Semiconductor) capacitors the main difference is that instead of the metal contact the insulator (more general than oxide) is contacted by a liquid electrolyte of which the pH shall be measured. The physical detection principle may be the same as for Ion Sensitive Field Effect Transistors (ISFET), the pH dependence of the dielectric's (insulator) surface potential; however the signal transduction may be different. In contrast to the ISFET a pH change may not modulate the transistor current but may cause a shift in the C-V curve. The electrolyte DC potential is again controlled with a reference electrode. In particular, the voltage at the reference electrode may be used in order to calculate the pH level. For measuring the capacitance an application of a small AC signal may be used.

The aspects and exemplary embodiments defined above and further aspects of the invention are apparent from the example of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 schematically illustrates an Ion Sensitive Field Effect Transistor (ISFET)

FIG. 2 schematically illustrates C-V curves measured by an Electrolyte Insulator Semiconductor (EIS) capacitor.

FIG. 3 schematically illustrates processing steps of producing a chip integrated ion sensor according to an exemplary embodiment.

FIG. 4 schematically illustrates a top view of chip integrated ion sensors.

### DESCRIPTION OF EMBODIMENTS

The illustration in the drawing is schematically. In different drawings, similar or identical elements are provided with similar or identical reference signs.

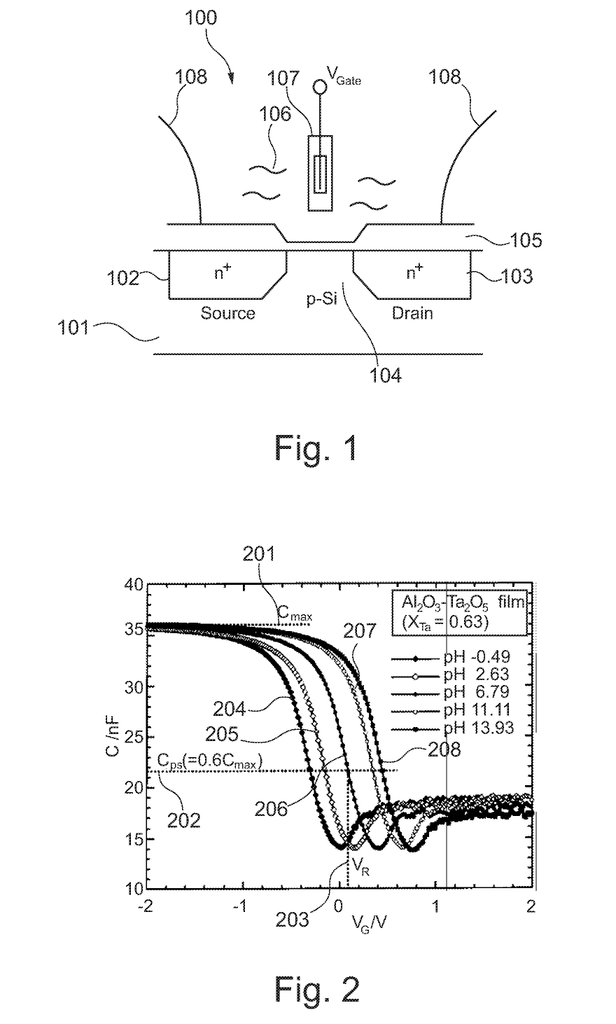

In the following an exemplary embodiment of a chip integrated ion sensor will described in more detail with reference to the FIGS. 1 to 4.

FIG. 1 schematically illustrates an Ion Sensitive Field Effect Transistor (ISFET) 100 which is helpful for understanding the present invention and which is described in “Thirty years of ISFETOLOGY What happened in the past 30 years and what may happen in the next 30 years. P. Bergveld, Sensors and Actuators B 88 (2003) 1-20. The ISFET 100 comprises a substrate 101 in which a source region 102 and a drain region 103 is formed. Between the source and the drain regions a channel region 104 is formed and a gate insulating layer 105 is formed on top of the source region 102, drain region 103 and channel region 104. An electrolyte 106 to be analyzed may be brought into contact with the gate insulating layer 105 and may form the gate of the ISFET 100. The gate voltage VGate (i.e. electrolyte voltage) may be controlled by a reference electrode 107. To enable the analyzing of liquid electrolytes the ISFET may comprise walls 108 forming a tank into which the liquid may be filled.

FIG. 2 schematically illustrates capacitance-voltage (C-V) curves measured by an Electrolyte Insulator Semiconductor (EIS) capacitor as described for example in: “Development of a Wide Range pH Sensor based on Electrolyte-Insulator Semiconductor Structure with Corrosion-Resistant Al₂O₃-Ta₂O₅ and Al₂O₃-ZrO₂ Double-Oxide Thin Films.”, Shoji Yoshida, Nobuyoshi Hara, and Katsuhisa Sugimoto, Journal of The Electrochemical Society, 151 (3) H53-H58 (2004). In particular, five C-V curves are depicted in FIG. 2 corresponding to five different pH values of electrolytes or buffer solutions. The C-V curves depict the capacitance over the voltage. In FIG. 2 the maximum capacitance Cmax is indicated by the dotted line 201. Additionally a second dotted line 202 indicates a capacitance Cps of 0.6 time of Cmax which can be selected as the constant predetermined capacitance level. A third dotted line 203 indicates the voltage level of the reference electrode, which is used for achieving CPS for a certain electrolyte pH. A first C-V curve 204 indicates the course for a pH level of −0.49, while a second C-V curve 205 indicates the course for a pH level of 2.63. A third C-V curve 206 indicates the course for a pH level of 6.79, while a fourth C-V curve 207 indicates the course for a pH level of 11.11. A fifth C-V curve 208 indicates the course for a pH level of 13.93. As can be seen from FIG. 2 at a fixed Cps the different pH levels correspond to different voltages so that it is possible to deduct the pH level or value from the voltage value applied to the reference electrode.

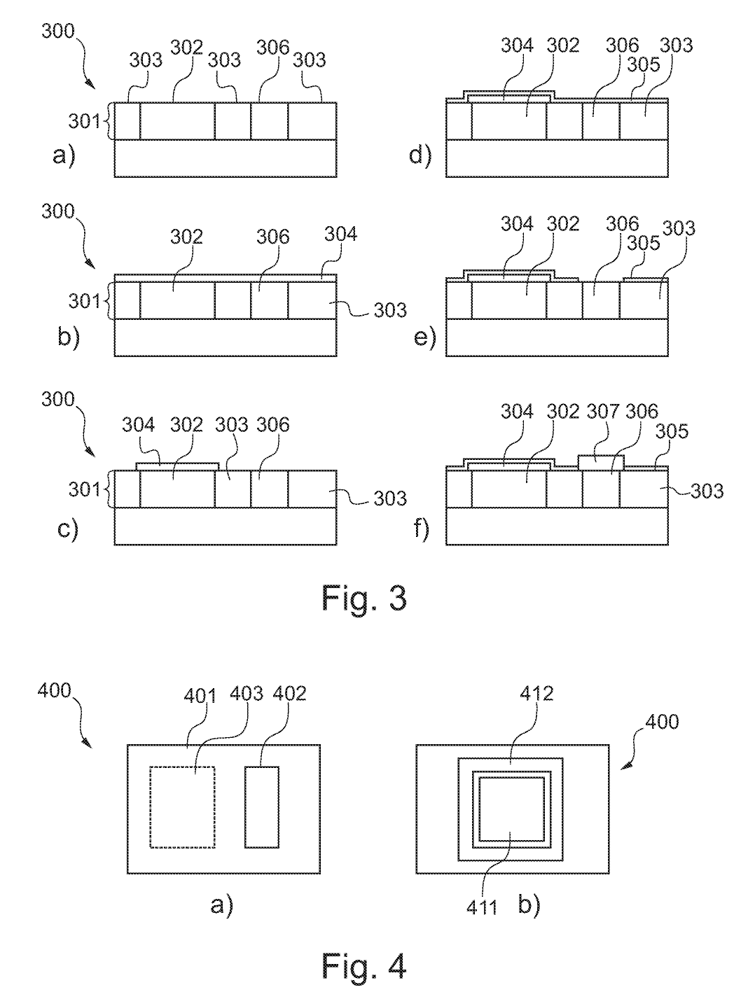

FIG. 3 schematically illustrates processing steps of producing a chip integrated ion sensor according to an exemplary embodiment. As mentioned above the chip integrated ion sensor, e.g. a pH sensor, is added on top of an existing (CMOS) chip. The main steps may include: semiconductor deposition, doping and patterning; deposition of the dielectric, deposition of the reference electrode; packaging of the device.

FIG. 3 describes the individual steps in more detail. In particular, FIG. 3a shows a CMOS chip 300 that has finished standard processing. Its top layer 301 comprises the metal contacts 302 and 306 for the sensors and bondpads (not shown) which are embedded in the passivation stack 303. The passivation stack may be formed by various silicon nitride and oxide layers to protect the circuits from moisture and ions. The top surface of the CMOS chip 300 may optionally be planarized, e.g. by chemical mechanical polishing, to obtain a smooth surface. Next the semiconductor layer 304, e.g. silicon, is deposited, e.g. by PVD, CVD, or ALD, wherein the layer thickness may range from around 50 nm to several μm; FIG. 3b. The semiconductor layer 304 may be doped during deposition, e.g. using suitable precursor gasses, or afterwards, e.g. using implantation, to set the flatband voltage such that it is negative throughout the entire pH range.

In the following steps the semiconductor layer 304 is patterned by lithography and etched such that it only remains on one electrode 302, as shown in FIG. 3c.

Then a dielectric layer 305 is deposited which may form the sensor dielectric, as shown in FIG. 3d. For the dielectric layer different materials are suitable depending on the desired sensitivity level and corrosion resistance level. For example, Ta₂O₅, SiO₂, TiO₂, Si₃N₄, Al₂O₃, SnO₂, or ZrO₂ or the like may be used. The thickness of the dielectric layer 305 may range between 10 nm and several hundred nanometres. Alternatively, also mixed materials can be used, e.g. Ta₂O₅ with Al₂O₃ or stacks of different materials e.g. SiO₂ with Ta₂O₅ on top.

Afterwards the sensor dielectric layer 305 is selectively removed on the contact area 306 for a reference electrode, e.g. by lithographic patterning of photo resist, etch of dielectric and resist removal, as shown in FIG. 3e.

Usually an Ag/AgCl reference electrode 307 may be used but also other chemically resistant metal halogenides and mixed oxides are conceivable as shown in FIG. 3f. Methods for depositing an Ag/AgCl reference electrode include (but are not restricted to) uniform deposition of an Ag layer and selective removal on all locations except for the contact (lithography and etch; alternatively lift-of technique i.e. first lithography then metal deposition and resist removal). Then the Ag/AgCl layer is deposited electrochemically, alternatively Cl-ions may be implanted into the Ag to from the AgCl, preferably only a very shallow implementation is performed. Another method is to deposit a polymer paste that contains the metal halogenide e.g. by screen printing or inkjet printing. Depending on the chemistry a hardening/sinter step may be required afterwards. In order to make the potential of the Ag/AgCl electrode (reference potential) independent of the Cl-concentration in the electrolyte a Cl-buffer layer may be processed on top of the Ag/AgCl reference electrode. Such a Cl-buffer layer may be formed by a porous matrix that contains for example KCl (e.g. Agar layer with KCl) with optional diffusion barrier on top (e.g. PVC). The Cl-buffer layer may be deposited by inkjet or screen printing, for example. This may be the final step for producing the chip integrated ion sensor and the sensors may now be ready for packaging.

The above described process represents a simple process integration scheme; of course more complex flows with additional steps may be possible. Also the geometry/layout of the electrodes may be different, cf. FIG. 4b, where the reference electrode surrounds the sensor electrode and the dielectric is removed everywhere except on top of the sensor electrode, for example.

In general all known deposition techniques may be used, e.g. PVD, CVD, or ALD or sputtering. However, it should be noted that the forming of the EIS structure should only include process steps ensuring that the preprocessed chip is not damaged or weakened, e.g. a suitable temperature range should be observed.

FIG. 4 schematically illustrates a top view of chip integrated ion sensors 400. In particular, FIG. 4a depicts a pH sensor manufactured according to the process steps above. The entire surface is covered by the dielectric layer 401 except for the reference electrode 402. The active sensor electrode area, which is covered by the dielectric layer, is indicated by the black lined rectangle 403. The advantage of this design may be that the dielectric layer also acts as additional protective layer in addition to the passivation stack. FIG. 4b shows an alternative layout wherein a reference electrode 412 surrounds the sensor electrode and the dielectric layer 411 is removed everywhere except on top of the sensor electrode.

Alternative to the above described two electrode layout or configuration a three electrode configuration may be possible. Such a three electrode layout may reduce current flow across the reference electrode during measurement. This may cause a shift in potential of the electrolyte and thus errors in the flatband/gate voltage and pH values, e.g. if the reference electrode is not an ideally non-polarizable electrode. To avoid these issues three electrode configurations and so called potentiostats may be used comprising a sensor or working electrode, which may be covered by the dielectric, a reference electrode and a counter electrode that may take all currents from the working electrode thus omitting any current (and potential shift) across the reference electrode. By adding the counter electrode to the design above and appropriate electronic circuits (potentiostat) to the chip it may be possible to realize such a fully integrated three electrode system. The counter electrode may be formed by e.g. Pt, Ag/AgCl. This three electrode layout may be advantageous in case of high currents, e.g. in case of a thin dielectric layer on the sensor electrode, which may otherwise lead to an observable voltage drop across the reference electrode.

Finally, it should be noted that the above-mentioned embodiments illustrate rather then limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. In a device claim enumerating several means, several of these means may be embodied by one and the same item of software or hardware. The mere fact that certain measures are recited in mutually different dependent claims does not indicate that a combination of these measures cannot be used to advantage.

1. Chip integrated ion sensor comprising:
a substrate having arranged thereon:
an electrolyte insulator semiconductor structure; and
a reference electrode.

2. The ion sensor according to claim 1,
wherein the substrate forms a chip processed according to CMOS processes.

3. The ion sensor according to claim 1,
wherein the electrolyte insulator semiconductor structure forms a capacity, wherein the reference electrode is adapted to set a potential of an electrolyte.

4. The ion sensor according to claim 3, further comprising:
a dielectric layer; and
a sensor electrode,
wherein the dielectric layer is formed between the reference electrode and the sensor electrode.

5. The ion sensor according to claim 4,
wherein the sensor electrode forms a second electrode of the capacity; and
wherein the sensor electrode comprises a semiconductor material.

6. The ion sensor according to claim 5,
wherein the semiconductor material is doped.

7. The ion sensor according to claim 6,
wherein the ion sensor is adapted such that the reference electrode is negatively biased with respect to the dielectric layer.

8. The ion sensor according to claim 4,
wherein the ion sensor is adapted in such a way that a liquid the ion concentration of which has to be measured comes into contact with the dielectric layer.

9. The ion sensor according to claim 3, further comprising:
a control unit,
wherein the control unit is adapted to maintain a capacitance value of the capacity at a predetermined level.

10. The ion sensor according to claim 9,
wherein the control unit comprises a feedback loop that is adapted to adjust a voltage level on the reference electrode.

11. The ion sensor according to claim 10, further comprising:
a processing unit,
wherein the processing unit is adapted to calculate an ion concentration based on the voltage level on the reference electrode.

12. The ion sensor according to claim 1,
wherein the substrate is formed by a chip which comprises a plurality of electronic circuits.

13. The ion sensor according to claim 12,
wherein the plurality of electronic circuits comprises at least one out of the group of electronic circuits consisting of:
data acquisition circuits;
processing circuits;
memory circuits;
power module; and RFID unit.

14. The ion sensor according to claim I, further comprising:
a third electrode forming a counter electrode.

15. The ion sensor according to claim 14, further comprising:
an integrated potentiostat that is adapted to control the counter electrode.

16. A method of manufacturing a chip integrated electrolyte insulator semiconductor ion sensor, the method comprising the method steps:
providing a substrate comprising at least one electronic component; and
forming an ion sensor on the substrate; and
forming a reference electrode of the substrate.
